(19) United States
(12) Patent Application Publication
(10) Pub. No.: US 2008/0068905 A1
(43) Pub. Date: Mar. 20, 2008

(54) Reparable semiconductor memory device

(76) Inventor: Dong-Min Kim, Seoul (KR)

Correspondence Address: LEE & MORSE, P.C., 3141 FAIRVIEW PARK DRIVE, SUITE 500, FALLS CHURCH, VA, 22042, US

(21) Appl. No.: 11/902,114

(22) Filed: Sep. 19, 2007

(30) Foreign Application Priority Data
Sep. 20, 2006 (KR) 10-2006-0091374

(51) Int. Cl. G11C 29/00; G11C 17/18

(52) U.S. Cl. 365/200; 365/225.7

(57) ABSTRACT

A semiconductor memory device, including a plurality of cell arrays, each cell array configured to receive and output data through first data IO lines and including at least one block having memory cells corresponding to a plurality of column selecting lines, a redundancy cell array configured to receive and output data through redundancy data IO lines and including redundancy memory cells corresponding to n redundancy column selecting lines, 2^{m} switching circuits configured to operate in correspondence with 2^{m} line selecting signals, the switching circuits configured to transmit data from second data IO lines to first data IO lines or to redundancy data IO lines, n switch selecting portions each having m fuses, the switch selecting generating portions configured to program the second fuses to generate 2^{m} switch control signals, and 2^{m} selecting signal generating portions configured to output line selecting signals.

### BACKGROUND OF THE INVENTION

1. Field of the Invention

Embodiments relate to a reparable semiconductor memory device. More particularly, embodiments relate to a reparable semiconductor memory device in which a number of fuses used to select a redundancy data IO line and a repairing time are reduced.

2. Description of the Related Art

In semiconductor devices, such as memory devices, when even a single unit cell includes a defect that causes the cell to function improperly, the device may be regarded as defective. However, it may be counterproductive to discard the whole device due to only a few defective cells. Accordingly, defective cells in a memory device may now be replaced with pre-fabricated redundancy cells to save the device. As a result, yield may increase and production cost may decrease.

A repair procedure using redundancy cells may be provided for by fabricating redundancy rows and redundancy columns for a cell array beforehand, and then replacing a defective row or column of a memory cell with a redundancy row or column. For example, when a defective memory cell is detected through testing after wafer processing is completed, a program may be executed in an internal circuit to replace an address of the defective cell with an address of a redundancy cell. Accordingly, when an address signal corresponding to a defective line is input during operation of the semiconductor memory device, the device may thus access a redundancy line instead of the defective line.

The conventional semiconductor memory device may include a switching fuse portion for each switching circuit, in order to use a redundancy data IO line when the defective memory cell is replaced with a redundancy memory cell. Each switching fuse portion may include a number of fuses equal to the number of redundancy row or columns, which may make layout of the semiconductor memory device difficult due to a large number of fuses. Further, the large number of fuses may require a significant time to program, which may lengthen the amount of time required to effect repairs in the semiconductor memory device.

### SUMMARY OF THE INVENTION

Embodiments are therefore directed to a reparable semiconductor memory device and associated method, which substantially overcome one or more of the problems due to the limitations and disadvantages of the related art.

It is therefore a feature of an embodiment to provide a reparable semiconductor memory device having a reduced number of fuses.

It is therefore another feature of an embodiment to provide a reparable semiconductor memory device that provides a reduced programming time.

At least one of the above and other features and advantages may be realized by providing a semiconductor memory device, including a plurality of cell arrays, each cell array configured to receive and output data through first data IO lines and including at least one block having memory cells corresponding to a plurality of column selecting lines, a redundancy cell array configured to receive and output data through redundancy data IO lines and including redundancy memory cells corresponding to n redundancy column selecting lines, 2^{m} switching circuits configured to operate in correspondence with 2^{m} line selecting signals, the switching circuits configured to transmit data from second data IO lines to first data IO lines or to redundancy data IO lines, n fuse boxes having first fuses, the fuse boxes configured to program the first fuses to generate n redundancy column enable signals that designate respective lines of the n redundancy column selecting lines, n switch selecting signal generating portions each having m second fuses, the switch selecting signal generating portions configured to program the second fuses to generate switch selecting signals that designate a block selected by the n redundancy column enable signals, n control signal generating portions configured to combine the n redundancy column enable signals and the switch selecting signals, and to generate the 2^{m} switch control signals, and 2^{m} selecting signal generating portions configured to receive and combine switch control signals and to output line selecting signals in correspondence with a column selecting line enable signal.

Each switch selecting signal generating portion may include a master selecting fuse portion having a master selecting fuse, the master selecting fuse portion determining a use of the switch selecting signal generating portion and outputting a block fuse disable signal when the master selecting fuse is in a blown-off state, and m selecting fuse portions each having a second fuse, the selecting fuse portions configured to output the switch selecting signal and an inverted switch selecting signal in correspondence with a blown-off state of the second fuse.

Each control signal generating portion may include a block selecting portion having 2^{m} switch selecting lines connected in parallel, wherein one switch selecting line is activated in response to one among different combinations of the switch selecting signal and the inverted switch selecting signal, and a control signal output portion configured to output the switch control signal in response to an output signal of each switch selecting line and the redundancy column enable signal.

Each switch selecting line may have m transistors that are serially connected, and each of the m transistors may operate in correspondence with a switch selecting signal or inverted switch selecting signal supplied from the corresponding selecting fuse portion among the m selecting fuse portions.

The control signal output portion may include 2^{m} AND gates each of which logically ANDs a received one of the 2^{m} switch selecting lines with a received redundancy column enable signal output from the fuse box corresponding to the switch selecting signal generating portion, the AND gates outputting the switch control signals.

Each control signal generating portion may further include a transistor connected between a power voltage and the block selecting portion, the transistor activating the control signal generating portion in response to an inverted power stabilizing signal.

Each switching circuit may include a first transmission gate connecting a predetermined number of the first data IO lines to a predetermined number of the second data IO lines and controlled by an inverted line selecting signal, and a second transmission gate connecting a predetermined number of the redundancy data IO lines to a predetermined number of the second data IO lines and controlled by a line selecting signal.

Each fuse box may include a master fuse portion having a master fuse determining a use of the fuse box and configured to output a fuse box disable signal in response to a blown-off state of the master fuse, a plurality of fuse portions respectively having the first fuses and configured to output a selecting signal and an inverted selecting signal in correspondence with a blown-off state of the first fuse, a fuse coding portion configured to compare an externally-supplied address to the selecting signals and the inverted selecting signals output from the fuse portions, and configured to output a result of the comparison, and a redundancy column enable signal outputting portion configured to receive, logically AND, and invert the output of the fuse coding portion, and configured to output the redundancy column enable signal in correspondence with the fuse box disable signal.

The semiconductor memory device may further include a control portion configured to output a column selecting line enable signal, the column selecting line enable signal signaling an activation time for a column selecting line.

Each selecting signal generating portion may include a power voltage transistor connected to a power voltage and operating in correspondence with the column selecting line enable signal, a ground voltage transistor connected to a ground voltage, the ground voltage transistor operating in correspondence with the column selecting line enable signal and opposite to the power voltage transistor, n transistors connected in parallel between the power voltage transistor and the ground voltage transistor and operating in correspondence with respective switch control signals output from the switch selecting portion, and a latch connected to power voltage transistor in common with corresponding connections to the n transistors, the latch configured to output the line selecting signal.

Each block may be provided with a number of first data IO lines that is the same as the number of memory cells corresponding to one column selecting line.

Each block may be provided with a number of second data IO lines that is the same as the number of first data IO lines connected to each block.

The redundancy cell array may be provided with a number of redundancy data IO lines that is the same as the number of redundancy memory cells corresponding to the redundancy column selecting line.

### BRIEF DESCRIPTION OF THE DRAWINGS

The above and other features and advantages will become more apparent to those of ordinary skill in the art by describing in detail example embodiments thereof with reference to the attached drawings in which:

FIG. 1 illustrates a block diagram of a semiconductor memory device having a redundancy data IO line according to an example embodiment;

FIG. 2 illustrates a circuit diagram of a switching circuit according to an embodiment;

FIG. 3 illustrates a block diagram of a fuse box according to an example embodiment;

FIG. 4A illustrates a block diagram of a switch selecting signal generating portion according to an example embodiment;

FIG. 4B illustrates a circuit diagram of a selecting fuse portion shown in FIG. 4A;

FIG. 5 illustrates a circuit diagram of a control signal generating portion according to an example embodiment; and

FIG. 6 illustrates a circuit diagram of a selecting signal generating portion according to an example embodiment.

### DETAILED DESCRIPTION OF THE INVENTION

Korean Patent Application No. 10-2006-0091374, filed on Sep. 20, 2006, in the Korean Intellectual Property Office, and entitled: “Semiconductor Memory Device,” is incorporated by reference herein in its entirety.

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

A semiconductor memory device according an embodiment may include a number of switch selecting portions that is equal to a number of redundancy column selecting lines, and each switch selecting portion may designate a corresponding block by using fuses. The number of fuses of the switching selecting portion may be equal to or less than “m”, where the number of blocks is equal to or less than 2^{m} and m is a positive integer.

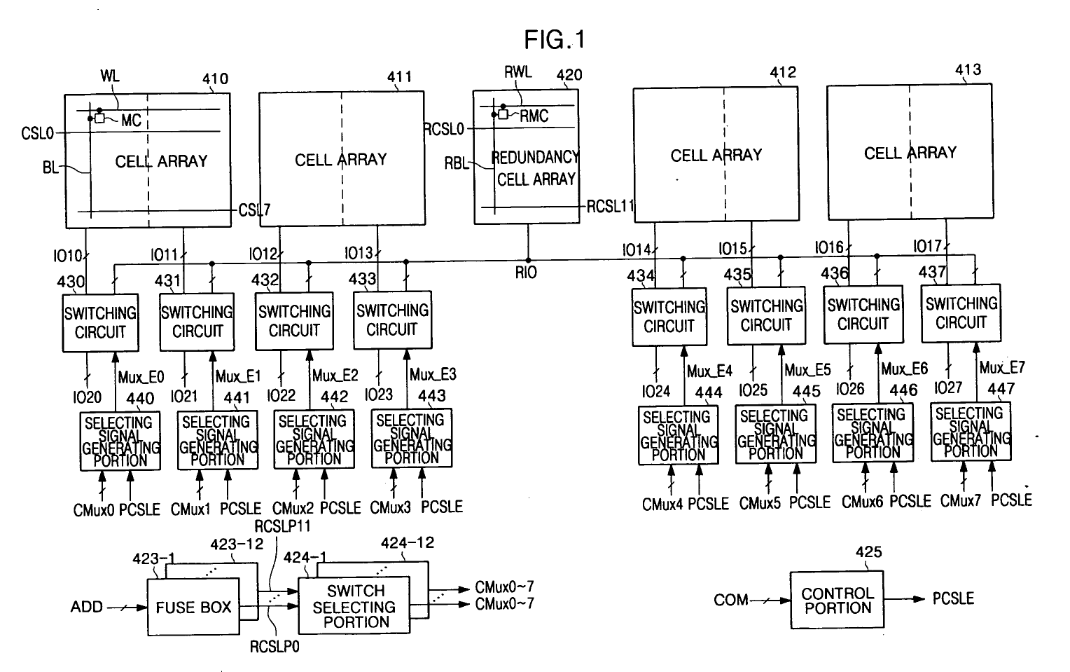

FIG. 1 illustrates a block diagram of a semiconductor memory device having a redundancy data IO line according to an example embodiment.

In the semiconductor memory device of FIG. 1, one or more repair units may be configured. One redundancy cell array 420 may be provided for a predetermined number of cell arrays, e.g., four cell arrays 410-413. Each of the cell arrays 410-413 may include a plurality of memory cells MC between a plurality of word lines WL and a plurality of bit lines BL. The memory cells MC connected to a word line WL selected by a row address of an address ADD that is externally supplied are activated. A predetermined number of bit lines BL may be activated by column selecting lines CSL0-CSL7 selected by a column address, so that a predetermined number of memory cells MC among the activated memory cells MC are connected to first data IO lines IO10-IO17. Each of the column selecting lines CSL0-CSL7 may activate one bit line BL, or may simultaneously activate a plurality of bit lines BL. In the following description, it is assumed that eight bit lines are activated in each cell array when one of the column selecting lines CSL0-CSL7 is selected, although the example embodiment is not limited thereto. Each of cell arrays 410-413 may be configured in block units, and the bit lines BL of each block may be activated by one of the column selecting lines CSL0-CSL7. Each of the cell arrays 410-413 may have, e.g., two blocks, and four bit lines BL may be activated in each block by one of the column selecting lines CSL0-CSL7.

The redundancy cell array 420 may include a plurality of redundancy memory cells RMC between a plurality of redundancy word lines RWL and a plurality of redundancy bit lines RBL. The redundancy cell array 420 may provide redundancy memory cells RMC to replace defective memory cells in the cell arrays 410-413.

If a memory cell MC selected by the address ADD is defective, the semiconductor memory device may inactivate the corresponding column selecting lines CSL0-CSL7 and activate redundancy column selecting lines RCSL0-RCSL11, in order to replace the selected memory cell MC with the redundancy memory cell RMC. Since four bit lines BL may be selected by one of the column selecting lines CSL0-CSL7 for each block in the cell arrays 410-413, four redundancy bit lines RBL may be selected by one of the redundancy column selecting lines RCSL0 RCSL11 in the redundancy cell array 420. Thus, when the column selecting lines CSL0-CSL7 are replaced with the redundancy column selecting lines CSL0-CSL11 of the defective memory cell MC, four memory cells MC may be replaced with four redundancy memory cells RMC.

First data IO lines IO10-IO17 may be connected to the selected memory cells MC of the cell arrays 410-413 to receive and output data. A redundancy data IO line RIO may be connected to the selected redundancy memory cells RMC of the redundancy cell array 420 to receive and output data. Since each block of the cell arrays 410-413 or the redundancy cell array 420 may receive or output data in a 4-bit unit, the first data IO lines IO10-IO17 and the redundancy data IO lines RIO may also be configured in a 4-bit unit.

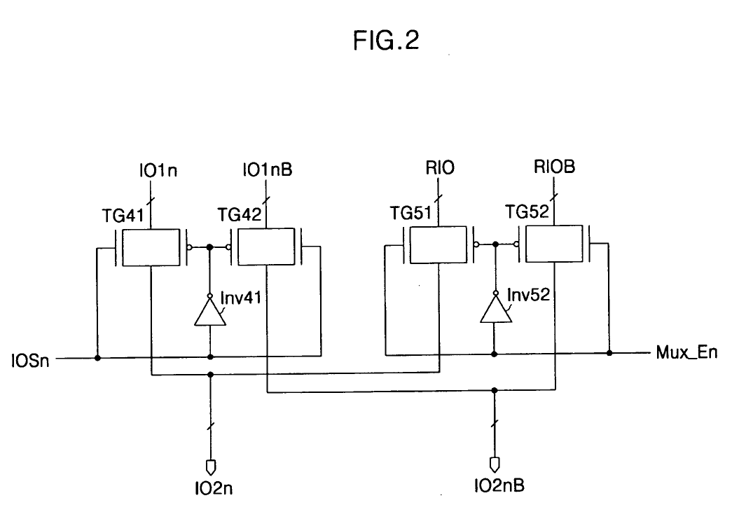

FIG. 2 illustrates a circuit diagram of a switching circuit according to an embodiment.

Switching circuits 430-437 may selectively connect the first data IO lines IO10-IO17 and the redundancy IO line RIO to second data IO lines IO20-IO27 in response to line selecting signals Mux_E0 to Mux_E7.

The switching circuits 430-437 may include transmission gates TG41 and TG42, which may connect the first data IO line pair IO1n and IOnB to the second data IO line pair IO2n and IO2nB in response to an IO signal IOSn. Transmission gates TG51 and TG52 may connect the redundancy data IO line pair RIO and RIOB to the second data IO line pair IO2n and IO2nB in response to the line selecting signal Mux_En. An inverted line selecting signal, or a signal generated from a discrete circuit, may be used as the IO signal IOSn.

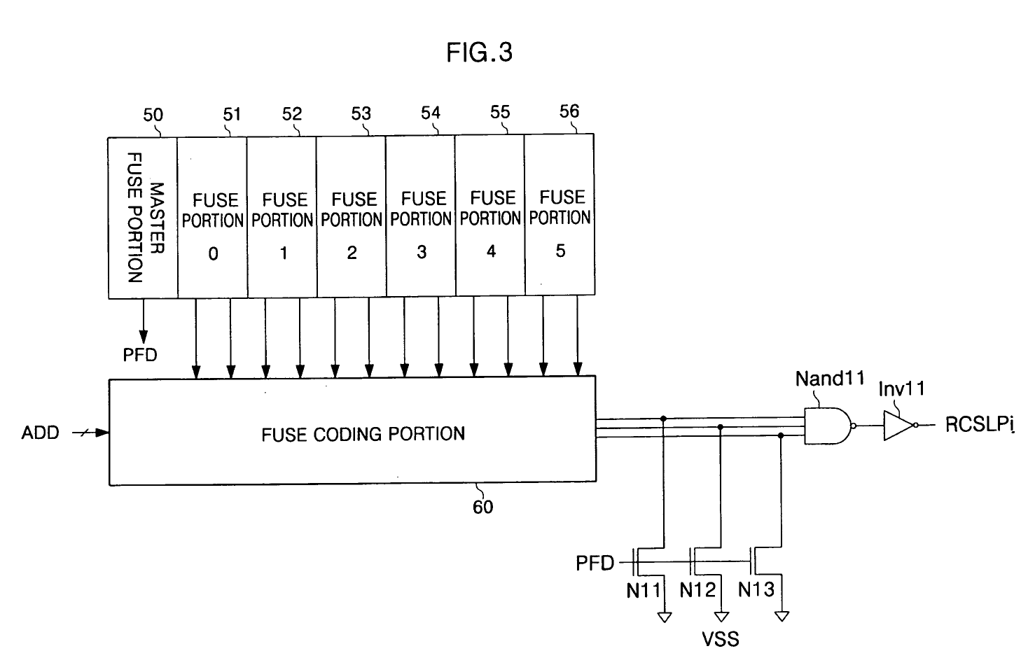

FIG. 3 illustrates a block diagram of a fuse box portion according to an example embodiment.

Fuse boxes 423-1 to 423-12 may be provided in a number n equal to the redundancy column selecting lines RCSL0-RCSL11 of the redundancy cell array 420, where n may be a positive integer, e.g., twelve. A master fuse portion 50 may include a fuse for determining whether to use the fuse boxes 423-1 to 423-12, and may output a fuse box disable signal PFD when the fuse boxes are not used.

A plurality of fuse portions 51 to 56 may designate the address ADD for the defective memory cell MC by blowing off fuses. In an exemplary case where a total of eight blocks are arranged and eight column selecting lines CSL0-CSL7 are arranged in each block, six fuse portions 51 to 56 may be provided in the fuse box illustrated in FIG. 3 (8 blocks×8 column selecting lines=64=2⁶).

A fuse coding portion 60 may compare the address for the defective memory cell designated by the fuse portions 51 to 56 to the externally applied address ADD, and may output a corresponding signal when the two addresses are the same. Two bits of the address ADD may be sequentially compared to two bits 51 and 52, 53 and 54, and 55 and 56 of the fuse portions 51 to 56, respectively, and when the same, a signal, e.g., a high level signal, may be output.

Three NMOS transistors N11 to N13 may disable the fuse boxes 423-1 to 423-12 in response to the fuse box disable signal PFD. For example, if the fuse box disable signal PFD has a high level, the NMOS transistors N11 to N13 may be turned on, so that only a signal having a low level is applied to an NAND gate Nand11. If the fuse box disable signal PFD has a low level, the NMOS transistors N11 to N13 may be turned off, so that the NAND gate Nand11 receives signals output from the fuse coding portion 60, and logically NANDs the signals and outputs the result. An inverter Inv11 may invert a signal output from the NAND gate Nand11 and may output the redundancy column enable signal RCSLPi.

Referring to FIGS. 1 and 3, the fuse boxes 423-1 to 423-12 may designate an address ADD for the column selecting lines CSL0-CSL7 of a block to be replaced with the corresponding redundancy column selecting lines RCSL0-RCSL11 by blowing off fuses. For example, the fuse boxes 423-1 to 423-12 may output a redundancy column enable signal RCSLPi for designating the corresponding redundancy column selecting line RCSL0 when an address of a block for the defective memory cell MC and the column selecting lines CSL0 to CSL7 designated by fuses is identical to the address ADD. In the case that twelve redundancy column selecting lines RCSL0-RCSL11 are provided, twelve fuse boxes 423-1 to 423-12 may also be provided, and twelve redundancy column enable signals RCSLP0 to RCSLP11 may be output.

Switch selecting portions 424-1 to 424-12 may be provided in a number equal to the number to the fuse boxes 423-1 to 423-12 and may receive the redundancy column selecting lines RCSL0 to RCSL11 output from the fuse boxes 423-1 to 423-12. The switch selecting portions 424-1 to 424-12 may output switch control signals CMux0 to CMux7 for selecting the corresponding switching circuits 430-437, respectively. Each of the switch selecting portions 424-1 to 424-12 may activate one of the switch control signals CMux0 to CMux7 and output the result.

A control portion 425 may output a column selecting line enable signal PCSLE for designating a time point for activating the column selecting line in response to a command COM applied from the external portion.

Selecting signal generating portions 440 to 447 may output line selecting signals Mux_E0 to Mux_E7 for controlling the corresponding switching circuits 430-437 in response to the switch control signals CMux0 to CMux7, respectively.

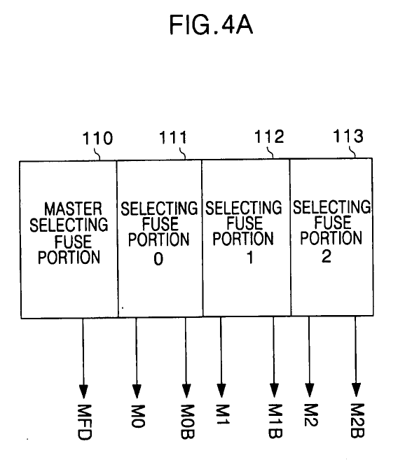

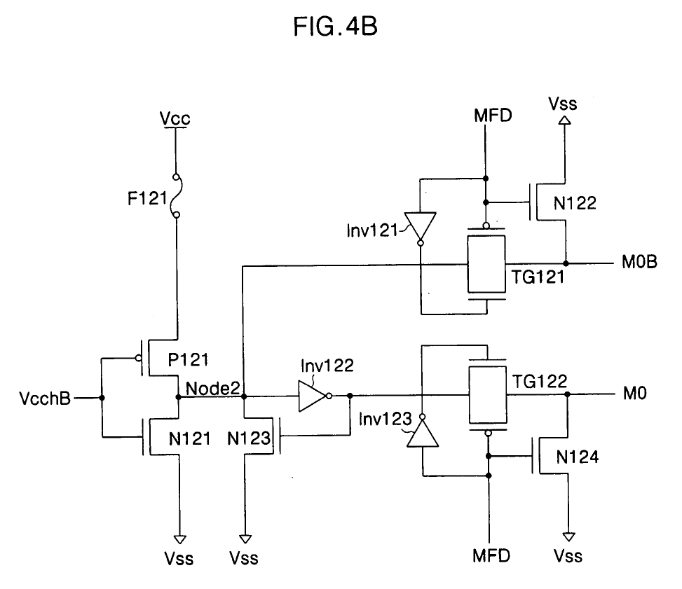

FIG. 4A illustrates a block diagram of a switch selecting signal generating portion according to an example embodiment.

The switch selecting portions 424-1 to 424-12 may each include the switch selecting signal generating portion shown in FIG. 4A, for generating a switch selecting signal for selecting each block, and a control signal generating portion, for combining the switching selecting signal and the redundancy column enable signals RCSLP0 to RCSLP11 to output a switch control signals CMux0 to CMux7 for controlling the switching circuits 430-437.

The switch selecting signal generating portion may include a master selecting fuse portion 110, which may be a fuse for determining whether to use the switch selecting portions 424-1 to 424-12. The master selecting fuse portion 110 may output a block fuse disable signal MFD when the switch selecting portions 424-1 to 424-12 is not used, i.e., when the master selecting fuse is in a blown-off state.

Selecting fuse portions 111-113 may be fuses for setting block information of a defective memory cell MC, and m selecting fuse portions may be provided when 2^{m} blocks are provided. In describing this embodiment, it will be assumed that eight blocks are arranged for each repair unit, and so three selecting fuse portions 111-113 may be provided.

The selecting fuse portions 111-113 may output respective switch selecting signals M0-M2 and respective inverted (bar) switch selecting signals M0B-M2B according to whether a fuse is blown off or not. Thus, eight blocks may be designated by combining the switch selecting signals M0-M2 and the inverted switch selecting signals M0B-M2B output from the three selecting fuse portions 111-113. If the number of blocks is less than 2^{m}, the master selecting fuse portion 110 may be omitted, and a combination of the switch selecting signals M0-M2 and the inverted switch selecting signals M0B-M2B for a block address which is not selected may substitute for the function of the master selecting fuse portion 110.

FIG. 4B illustrates a circuit diagram of a selecting fuse portion shown in FIG. 4A.

When the semiconductor memory device is powered on, the selecting fuse portion 111 may receive an inverted power stabilizing signal VcchB. The inverted power stabilizing signal VcchB may be a signal which is supplied at a low level when an electrical power of higher than a predetermined voltage level is applied to the semiconductor memory device.

If a state that a fuse F121 is not blown off, a PMOS transistor P121 and an NMOS transistor N121 may invert the inverted power stabilizing signal VcchB and output the result.

An inverter Inv122 and an NMOS transistor N123 may function as a latch that inverts and latches a signal of a second node Node2, and outputs the result.

A transmission gate TG121 may output the signal of the second node Node2 as the inverted switch selecting signal M0B in response to the block fuse disable signal MFD output from the master selecting fuse portion 110. A transmission gate TG122 may output an output of the inverter Inv122 as the switch selecting signal M0 in response to the block fuse disable signal MFD.

If the block fuse disable signal MFD output from the master selecting fuse portion 110 has a low level, the selecting fuse portion 111 may output the signal of the second node Node2 as the inverted switch selecting signal M0B, and may output the output of the inverter Inv122 as the switch selecting signal M0. If the block fuse disable signal MFD has a high level, the transmission gates TG121 and TG122 may not transmit the signal of the second node Node2 and the output of the inverter Inv122, but may output the switch selecting signal M0 and the inverted switch selecting signal M0B at a low level via NMOS transistors N122 and N124, which may be turned on in response to high level the block fuse disable signal MFD.

If the block fuse disable signal MFD is applied with a low level and the fuse F121 is not blown off, the second node Node2 may invert the inverted power stabilizing signal VcchB to a high level. As a result, the switch selecting signal M0 may be output with a low level, and the inverted switch selecting signal M0B may be output with a high level. If the fuse F121 is blown off, the second node Node2 may have a low level, so that the switch selecting signal M0 may be output with a high level, and the inverted switch selecting signal M0B may be output with a low level.

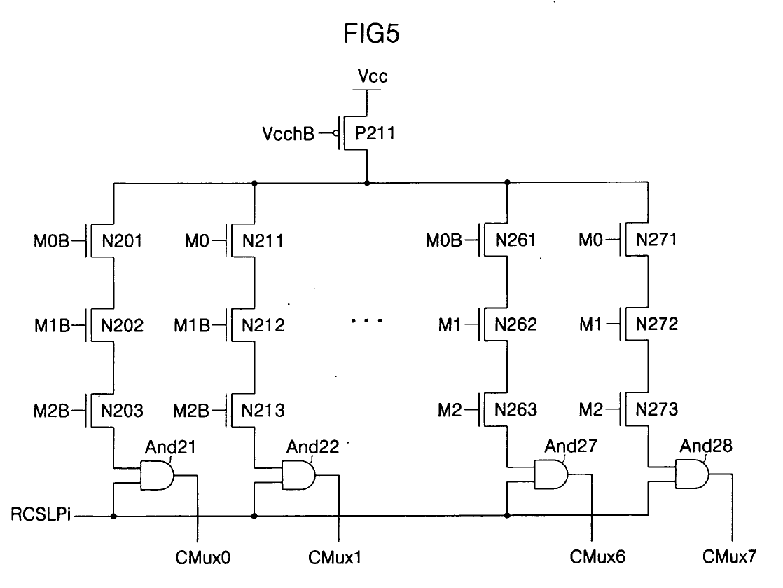

FIG. 5 illustrates a circuit diagram of a control signal generating portion according to an example embodiment.

The control signal generating portion may be a circuit in the switch selecting portion. The control signal generating portion may combine the switch selecting signal pairs M0 and M0B, M1 and M1B, and M2 and M2B with the redundancy column enable signal RCSLPi to designate a switching circuits 430-437 for selecting the redundancy IO line RIO.

A PMOS transistor P211 may function to activate the control signal generating portion and may be activated in response to the inverted power stabilizing signal VcchB. The inverted power stabilizing signal VcchB may be at a low level after a lapse of a predetermined time after the semiconductor memory device is powered on, and thus the control signal generating portion may always be activated.

Groups of NMOS transistors N201-N203, N211-N213, . . . , N261-N263, and N271-N273 may be serially connected, and may receive the corresponding switch selecting signals M0, M1, and M2 and the inverted switch selecting signals M0B, M1B, and M2B, respectively. The NMOS transistors N201 to N273 may be serially connected three by three so as to correspond to the three selecting fuse portions 111-113 of FIG. 4A. Eight transistor groups, each including the three NMOS transistors serially connected, may be connected in parallel in correspondence with eight blocks.

The NMOS transistors N201-N273 may receive the designated switch selecting signals M0-M2 or the inverted switch selecting signals M0B-M2B, respectively, and one transistor group from among the eight group's of three serially connected NMOS transistors N201-N203, . . . , N271-N273 may be activated by the switch selecting signal pairs M0 and M0B, M1 and M1B, and M2 and M2B, which are output from the selecting fuse portions 111-113 shown in FIG. 4A. For example, if the switch selecting signals M0-M2 output from the switch selecting signal generating portion are “100”, only the NMOS transistors N211-N213 of the second line may be turned on.

The redundancy column enable signal RCSLPi may be set in advance to correspond to a used one among the redundancy column selecting lines RCSL0-RCSL11. For example, if the fourth redundancy column selecting line RCSL3 is used, the redundancy column enable signal RCSLP3 may be output from the fuse box 23-4 corresponding to the fourth redundancy column selecting line RCSL3, and signals supplied through the NMOS transistors N211-N213 of the second line may be logically ANDed by an AND gate And22 to output a switch control signal CMux1.

If the fifth redundancy column selecting line RCSL4 replaces one of the column selecting lines CSL0-CSL7 of the second block, the redundancy column enable signal RCSLP4 output from the fuse box 23-5 corresponding to the fifth redundancy column selecting line RCSL4 and signals supplied through the NMOS transistors N211-N213 of the second line may be logically ANDed by the AND gate And22 to output the switch control signal CMux1.

The switch control signals CMux0-CMux7 output from the control signal generating portion may contain information about each block and may be supplied directly to the switching circuits 430-437, so that the switching circuits 430-437 can select the redundancy data IO line RIO.

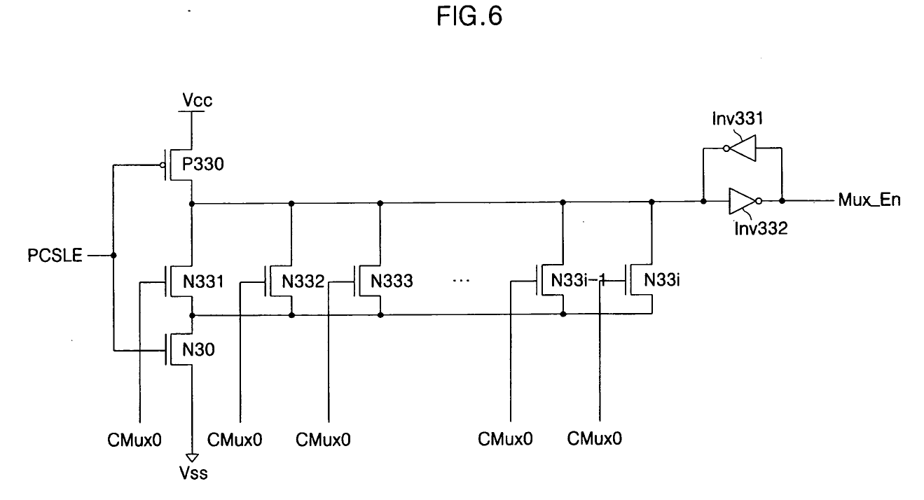

FIG. 6 illustrates a circuit diagram of a selecting signal generating portion according to an example embodiment.

The selecting signal generating portion may supply the switch control signals CMux0-CMux7 output from the control signal generating portion to the switching circuits 430-437 to control them. However, if the switch control signals CMux0-CMux7 respectively output from a plurality of control signal generating portions are commonly applied, signal stability may be degraded. The redundancy cell array having the twelve redundancy column selecting lines RCSL0-RCSL11 may have twelve control signal generating portions. Referring to FIG. 6, if the twelve switch control signals CMux0 generated from the twelve control signal generating portions are supplied to the switching circuit 430, a signal line may be lengthy, and noise may be generated as many signal lines are connected. Thus, the signal stability may be increased by using the selecting signal generating portion of FIG. 6.

Each selecting signal generating portion may include NMOS transistors N331-N331, which may be equal in number to the number of the redundancy column selecting lines RCSL0-RCSL11, e.g., twelve. The NMOS transistors N331-N331 may receive only a signal of a corresponding block among the switch control signals CMux0-CMux7 output from the control signal generating portion, respectively. In case of the selecting signal generating portion of the second block, the NMOS transistors N331-N331 receives the twelve switch control signals CMux1 corresponding to the second block, respectively.

If just one of the twelve selecting signal generating portions receives the switch control signals CMux0-CMux7 for the corresponding block, the selecting signal generating portion may output the line selecting signal Mux_En.

A conventional semiconductor device may have switching circuits in which each switching circuit has as many fuses as the number of redundancy columns to replace the data line with the redundancy data IO line. The conventional semiconductor memory device may have a switching fuse portion for each block. Eight switching fuse portions may include eight fuses, i.e., a number equal to the number of the redundancy column selecting lines, in order to select the redundancy data IO line when the redundancy memory cell for replacing the defective memory cell of the corresponding block is selected. Each of the eight switching fuse portions may have the twelve fuses, so that 96 fuses are used.

In contrast, a semiconductor memory device in accordance with an embodiment may have a number of switch selecting portions that is equal to the number redundancy columns and may use m fuses for the 2^{m} switching circuits. Accordingly, a semiconductor memory device according to an embodiment may be highly integrated and may enable efficient repair, since a time for blowing off fuses during a process for repairing the data line may be reduced. The semiconductor memory device of FIG. 1 may use 48 fuses, since each of the twelve switch selecting portions 424-1 to 424-12 may include four fuses. Accordingly, the number of fuses may be reduced, and thus a repairing time for the data line may be reduced.

Exemplary embodiments have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A semiconductor memory device, comprising:
a plurality of cell arrays, each cell array configured to receive and output data through first data IO lines and including at least one block having memory cells corresponding to a plurality of column selecting lines;
a redundancy cell array configured to receive and output data through redundancy data IO lines and including redundancy memory cells corresponding to n redundancy column selecting lines;
2^{m} switching circuits configured to operate in correspondence with 2^{m} line selecting signals, the switching circuits configured to transmit data from second data IO lines to first data IO lines or to redundancy data IO lines;
n fuse boxes having first fuses, the fuse boxes configured to program the first fuses to generate n redundancy column enable signals that designate respective lines of the n redundancy column selecting lines;
n switch selecting signal generating portions each having m second fuses, the switch selecting signal generating portions configured to program the second fuses to generate switch selecting signals that designate a block selected by the n redundancy column enable signals; n control signal generating portions configured to combine the n redundancy column enable signals and the switch selecting signals, and to generate the 2^{m} switch control signals; and
2^{m} selecting signal generating portions configured to receive and combine switch control signals and to output line selecting signals in correspondence with a column selecting line enable signal.

2. The semiconductor memory device as claimed in claim 1, wherein each switch selecting signal generating portion comprises:
a master selecting fuse portion having a master selecting fuse, the master selecting fuse portion determining a use of the switch selecting signal generating portion and outputting a block fuse disable signal when the master selecting fuse is in a blown-off state; and
m selecting fuse portions each having a second fuse, the selecting fuse portions configured to output the switch selecting signal and an inverted switch selecting signal in correspondence with a blown-off state of the second fuse.

3. The semiconductor memory device as claimed in claim 2, wherein each control signal generating portion comprises:
a block selecting portion having 2^{m} switch selecting lines connected in parallel, wherein one switch selecting line is activated in response to one among different combinations of the switch selecting signal and the inverted switch selecting signal; and
a control signal output portion configured to output the switch control signal in response to an output signal of each switch selecting line and the redundancy column enable signal.

4. The semiconductor memory device as claimed in claim 3, wherein:
each switch selecting line has m transistors that are serially connected, and
each of the m transistors operates in correspondence with a switch selecting signal or inverted switch selecting signal supplied from the corresponding selecting fuse portion among the m selecting fuse portions.

5. The semiconductor memory device as claimed in claim 3, wherein the control signal output portion comprises 2^{m} AND gates each of which logically ANDs a received one of the 2^{m} switch selecting lines with a received redundancy column enable signal output from the fuse box corresponding to the switch selecting signal generating portion, the AND gates outputting the switch control signals.

6. The semiconductor memory device as claimed in claim 3, wherein each control signal generating portion further comprises a transistor connected between a power voltage and the block selecting portion, the transistor activating the control signal generating portion in response to an inverted power stabilizing signal.

7. The semiconductor memory device as claimed in claim 1, wherein each switching circuit comprises:
a first transmission gate connecting a predetermined number of the first data IO lines to a predetermined number of the second data IO lines and controlled by an inverted line selecting signal; and
a second transmission gate connecting a predetermined number of the redundancy data IO lines to a predetermined number of the second data IO lines and controlled by a line selecting signal.

8. The semiconductor memory device as claimed in claim 1, wherein each fuse box comprises:
a master fuse portion having a master fuse determining a use of the fuse box and configured to output a fuse box disable signal in response to a blown-off state of the master fuse;
a plurality of fuse portions respectively having the first fuses and configured to output a selecting signal and an inverted selecting signal in correspondence with a blown-off state of the first fuse;
a fuse coding portion configured to compare an externally-supplied address to the selecting signals and the inverted selecting signals output from the fuse portions, and configured to output a result of the comparison; and
a redundancy column enable signal outputting portion configured to receive, logically AND, and invert the output of the fuse coding portion, and configured to output the redundancy column enable signal in correspondence with the fuse box disable signal.

9. The semiconductor memory device as claimed in claim 1, further comprising a control portion configured to output the column selecting line enable signal, the column selecting line enable signal signaling an activation time for a column selecting line.

10. The semiconductor memory device as claimed in claim 1, wherein each selecting signal generating portion comprises:
a power voltage transistor connected to a power voltage and operating in correspondence with the column selecting line enable signal;
a ground voltage transistor connected to a ground voltage, the ground voltage transistor operating in correspondence with the column selecting line enable signal and opposite to the power voltage transistor;
n transistors connected in parallel between the power voltage transistor and the ground voltage transistor and operating in correspondence with respective switch control signals output from the switch selecting portion; and
a latch connected to power voltage transistor in common with corresponding connections to the n transistors, the latch configured to output the line selecting signal.

11. The semiconductor memory device as claimed in claim 1, wherein each block is provided with a number of first data IO lines that is the same as the number of memory cells corresponding to one column selecting line.

12. The semiconductor memory device as claimed in claim 11, wherein each block is provided with a number of second data IO lines that is the same as the number of first data IO lines connected to each block.

13. The semiconductor memory device as claimed in claim 1, wherein the redundancy cell array is provided with a number of redundancy data IO lines that is the same as the number of redundancy memory cells corresponding to the redundancy column selecting line.
